(19) United States
(12) Patent Application Publication
(10) Pub. No.: US 2025/0140951 A1
(43) Pub. Date: May 1, 2025

(54) SELECTIVE DISABLING OF BATTERIES FROM BATTERY PACK BASED ON PREDICTED LEVEL OF DENDRITE FORMATION

(71) Applicant: International Business Machines Corporation, Armonk, NY (US)

(72) Inventors: Sarbajit K. Rakshit, Kolkata (IN); Sridevi Kannan, Chennai (IN); Sathya Santhar, Chennai (IN)

(21) Appl. No.: 18/493,846

(22) Filed: Oct. 25, 2023

(51) Int. Cl. H01M 10/44; G01R 31/367; G01R 31/396; H01M 10/48; H01M 10/613

(52) U.S. Cl. CPC H01M 10/44; G01R 31/367; G01R 31/396; H01M 10/48; H01M 10/613

(57) ABSTRACT

According to one embodiment, a method, computer system, and computer program product for selective battery disabling is provided. The embodiment may include calculating a dendrite formation value of a cell within a battery pack based on captured sensor data. The embodiment may also include, in response to determining the dendrite formation value exceeds a safety threshold, disabling the cell.

### BACKGROUND

The present invention relates generally to the field of computing, and more particularly to processing of data for testing or for monitoring individual cells or groups of cells within a battery.

A battery pack is a set of any number of, preferably, identical batteries or individual battery cells. Battery packs may be configured in a series, parallel or a mixture of both in order to deliver the desired voltage, capacity, or power density. The term “battery pack” is often used in reference to cordless tools, radio-controlled hobby toys, and battery electric vehicles.

Components of battery packs include the individual batteries or cells, and the interconnects between them which provide electrical conductivity. Rechargeable battery packs often contain a temperature sensor, which the battery charger uses to detect the end of charging. Interconnects may also be found in batteries as they connect each cell, though batteries are most often arranged in series strings.

### SUMMARY

According to one embodiment, a method, computer system, and computer program product for selective battery disabling is provided. The embodiment may include calculating a dendrite formation value of a cell within a battery pack based on captured sensor data. The embodiment may also include, in response to determining the dendrite formation value exceeds a safety threshold, disabling the cell.

### BRIEF DESCRIPTION OF THE SEVERAL VIEWS OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. In the drawings:

FIG. 1 illustrates an exemplary networked computer environment according to at least one embodiment.

FIG. 2 illustrates an operational flowchart for a selective battery disabling process according to at least one embodiment.

FIG. 3 illustrates a functional block diagram of a battery pack temperature regulation system according to at least one embodiment.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

Embodiments of the present invention relate to the field of computing, and more particularly to processing of data for testing or for monitoring individual cells or groups of cells within a battery. The following described exemplary embodiments provide a system, method, and program product to, among other things, identify specific cells within a battery pack with dendrite formation exceeding a threshold and disablement of the identified cells to prevent short circuiting of the battery pack. Therefore, the present embodiment has the capacity to improve the technical field processing of data for testing or for monitoring individual cells or groups of cells within a battery by reducing the risks of dendrite formation in batteries and cells under specific conditions.

As previously described, a battery pack is a set of any number of, preferably, identical batteries or individual battery cells. Battery packs may be configured in a series, parallel or a mixture of both in order to deliver the desired voltage, capacity, or power density. The term “battery pack” is often used in reference to cordless tools, radio-controlled hobby toys, and battery electric vehicles.

Components of battery packs include the individual batteries or cells, and the interconnects between them which provide electrical conductivity. Rechargeable battery packs often contain a temperature sensor, which the battery charger uses to detect the end of charging. Interconnects may also be found in batteries as they connect each cell, though batteries are most often arranged in series strings.

When a battery pack contains groups of cells in parallel there are different wiring configurations which take into consideration the electrical balance of the circuit. Battery regulators are sometimes used to keep the voltage of each individual cell below its maximum value during charging so as to allow the weaker batteries to become fully charged, bringing the whole pack back into balance. Active balancing can also be performed by battery balancer devices which can shuttle energy from strong cells to weaker ones in real time for better balance. A well-balanced battery pack typically has a longer lifespan and delivers better performance.

A lithium-ion battery, which is typically used in srnartphones, power tools, and electric vehicles, consists of a cathode, an anode, a separator, and an electrode, and usually employs a liquid electrolyte solution. On the other hand, solid-state batteries use a solid electrolyte. These batteries have a higher energy density than their liquid electrolyte lithium-ion counterparts. They also have minimal to no explosion or fire risk, eliminating the need for safety components and freeing up space for more active materials to enhance battery capacity. This feature allows solid-state batteries to boost energy density per unit area as fewer batteries are required. Therefore, due to their high capacity, solid-state batteries are more suitable for electric vehicle battery systems.

A common cause of internal failure in batteries is the formation of lithium dendrite within individual cells. Lithium dendrite are metallic microstructures that form within battery cells on the anode during charging of a lithium-ion battery when a surplus of lithium ions accumulate on the anode surface when the anode is unable to absorb the ions. The formation of lithium dendrite occurs in branch-like projections on one electrode but will eventually bridge the electrolyte, which causes a short circuit of the lithium-ion battery cell. Typically, dendrite formation occurs more quickly when current flow is high or under temperatures outside of a specific range are encountered.

In any battery pack, each battery may have a different health status in terms of current dendrite formation and a dendrite formation rate on a respective battery cell's anode. In some circumstances, certain battery cells may have dendrite formation that exceeds a safety threshold at which further use or recharging of the battery cell may be at risk of short circuit or combustion. As such, it may be advantageous to, among other things, identify which batteries or cells within a battery pack are likely to have dendrite formation above a threshold value and avoid recharge and/or discharge of those cells or batteries.

According to at least one embodiment, a selective battery disabling program may analyze historical usage of each battery withing a battery pack, operation and environmental parameters during various usage conditions, and conduct periodic investigation of the status of the battery pack. The selective battery disabling program may utilize the information gleaned from the analysis to predict the value of dendrite formation on various cells or batteries within the battery pack, and which values of exceed a preconfigured threshold of dendrite formation for safe operation. For cells or batteries exceeding the preconfigured threshold of dendrite formation, the selective battery disabling program may disable current through the affected cells through one or more actions.

Any advantages listed herein are only examples and are not intended to be limiting to the illustrative embodiments. Additional or different advantages may be realized by specific illustrative embodiments. Furthermore, a particular illustrative embodiment may have some, all, or none of the advantages listed above.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

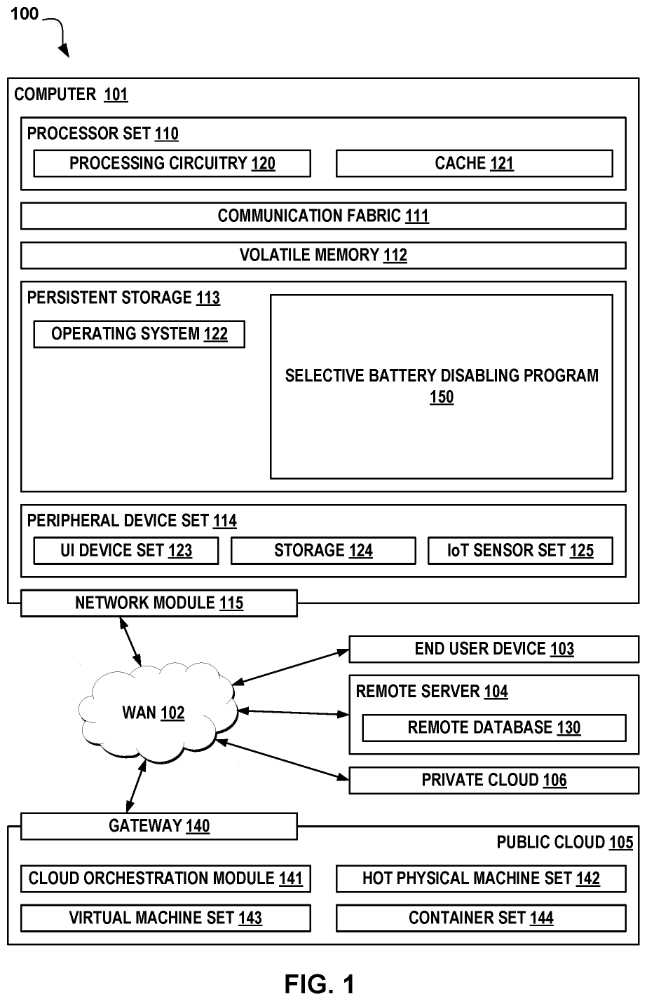

Referring now to FIG. 1, computing environment 100 contains an example of an environment for the execution of at least some of the computer code involved in performing the inventive methods, such as selective battery disabling program 150. In addition to selective battery disabling program 150, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and selective battery disabling program 150, as identified above), peripheral device set 114 (including user interface (UI), device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

Computer 101 may take the form of a desktop computer, laptop computer, tablet computer, smart phone, smart watch or other wearable computer, mainframe computer, quantum computer, or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, for illustrative brevity. Computer 101 may be located in a cloud, even though it is not shown in a cloud in FIG. 1. On the other hand, computer 101 is not required to be in a cloud except to any extent as may be affirmatively indicated.

Processor set 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in selective battery disabling program 150 in persistent storage 113.

Communication fabric 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, the volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid-state storage devices. Operating system 122 may take several forms, such as various known proprietary operating systems or open-source Portable Operating System Interface-type operating systems that employ a kernel. The code included in selective battery disabling program 150 typically includes at least some of the computer code involved in performing the inventive methods.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made though local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

Network module 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN 102 and/or LANs typically include computer hardware such as copper transmission cables, optical transmission fibers, wireless transmission, routers, firewalls, switches, gateway computers and edge servers.

End user device (EUD) 103 is any computer system that is used and controlled by an end user and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community, or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

According to at least one embodiment, the selective battery disabling program 150 may receive historical operational data for a battery pack of cells and/or batteries. In one or more embodiments, the selective battery disabling program 150 may perform a training period where it captures performance and operation data related to the battery pack, such as duration of usage, temperature generation, time from full charge to full depletion, and current through one or more cells. Utilizing the received or captured data, the selective battery disabling program 150 may calculate a value of dendrite formation associated with one or more cells or batteries within the battery pack. If the selective battery disabling program 150 determines the calculated value of dendrite formation exceeds a preconfigured threshold, the selective battery disabling program 150 may determine the cell or battery within the battery pack is at risk for a short circuit and no longer safe for normal operation under standard conditions. As such, the selective battery disabling program 150 may perform a corrective action on the cell or battery, such as, but not limited to, engaging a temperature regulation device within the battery pack, disabling current to the affected cell or battery, or disengaging the affected cell or battery from the battery pack.

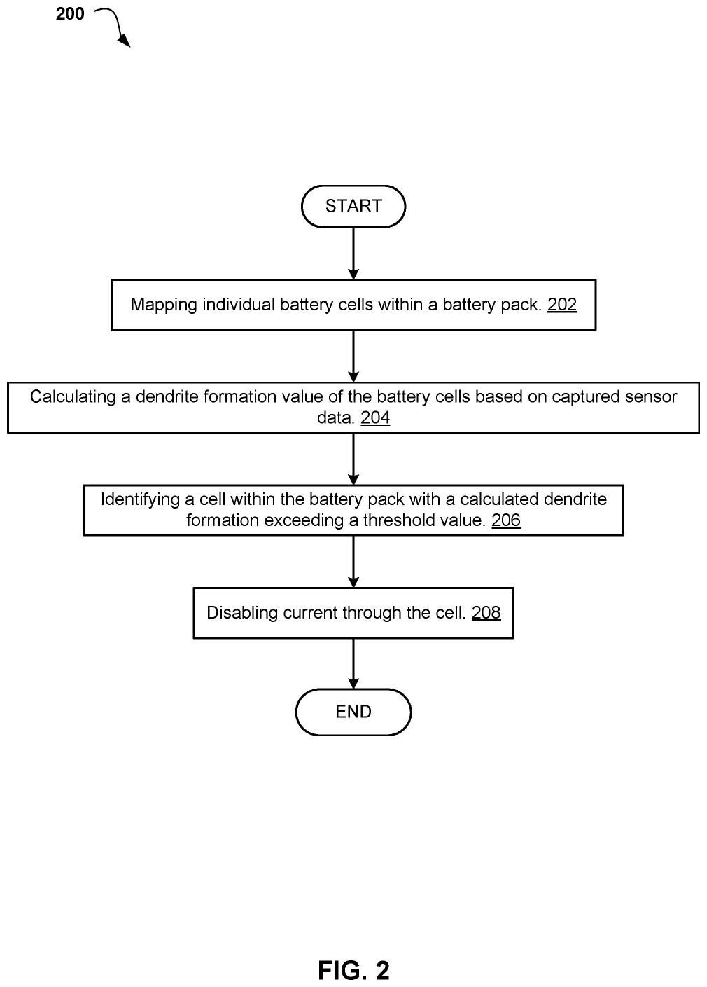

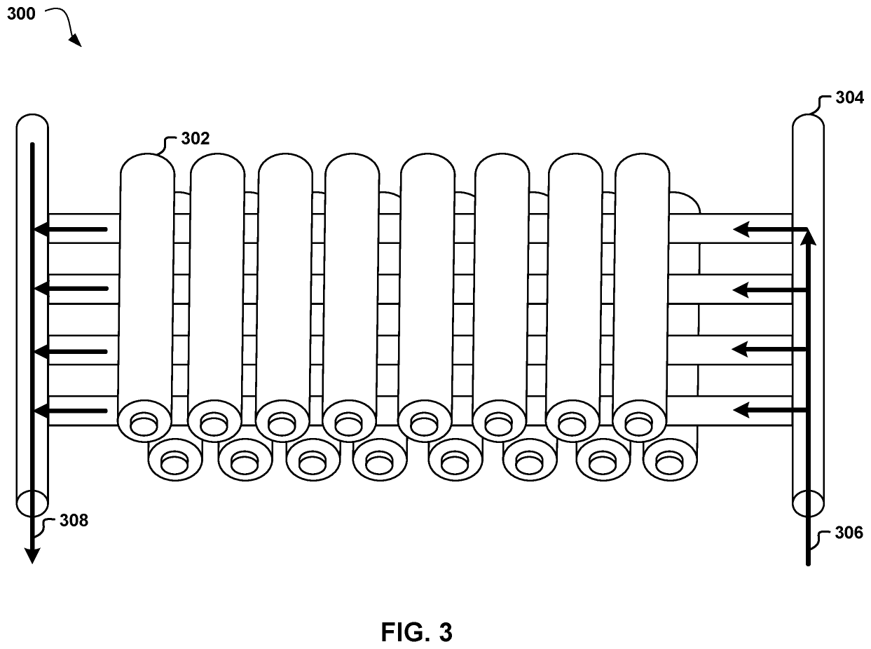

Additionally, prior to initially performing any actions, the selective battery disabling program 150 may perform an opt-in procedure. The opt-in procedure may include a notification of the data the selective battery disabling program 150 may capture and the purpose for which that data may be utilized by the selective battery disabling program 150 during data gathering and operation. Furthermore, notwithstanding depiction in computer 101, the selective battery disabling program 150 may be stored in and/or executed by, individually or in any combination, end user device 103, remote server 104, public cloud 105, and private cloud 106. The context-aware voice self-authorization method is explained in more detail below with respect to FIGS. 2-3.

Referring now to FIG. 2, an operational flowchart for a selective battery disabling process 200 according to at least one embodiment. At 202, the selective battery disabling program 150 maps individual battery cells within a battery pack. The selective battery disabling program 150 may map the individual battery cells within a battery pack through one or more sensors placed in or around the battery pack or in or around each cell. The one or more sensors may be equipped with location detections capabilities in order for the selective battery disabling program 150 to identify the location of the cells within the battery pack.

Additionally, the selective battery disabling program 150 may identify the placement of individual battery cells in the battery pack through other mapping techniques that may be in addition to, supplementary to, or in replacement of the information received from the sensors, such as preconfiguration by a developer or a user or through image recognition of an image captured by the user at direction of the selective battery disabling program 150. For example, a developer may indicate the location of each battery on an image or a digital rendering of the battery pack through a graphical user interface understandable by the selective battery disabling program 150.

Then, at 204, the selective battery disabling program 150 calculates a dendrite formation value of the battery cells based on captured sensor data. As previously described, the selective battery disabling program 150 may utilize one or more sensors within the battery pack to aid in mapping the cells within the battery pack. Despite the one or more sensors being capable of identifying the location of cells within the battery pack, the one or more sensors, or additional sensors within the battery pack, may be capable of collecting data related to calculating dendrite formation in the cells of the battery pack. The selective battery disabling program 150 may also utilize the one or more sensors or additional sensors to capture cell status information, such as, but not limited to, temperature, a charging detail, an available power state, a usage duration, an amount of recharge, an amount of discharge and any other information related to charge, discharge, operation, or environmental parameters of the cells, either individually or as a whole, in the battery pack.

The selective battery disabling program 150 may track current leakage from the cells or batteries within the battery pack when they are not in use based on the cell or battery's current health status derived from the cell status information. The selective battery disabling program 150 may determine a rate of dendrite formation within a cell or battery based on the current leakage over a preconfigured period of time.

In one embodiment, the selective battery disabling program 150 may capture the cell status information in real time as the data is collected by the sensors. However, in another embodiment, the selective battery disabling program 150 may receive the cell status information from the sensors periodically. The period of receipt of the cell status information may be time-based, such as daily or weekly, or operation-based, such as during a power-on operation or a power-down operation.

Using the elements of collected sensor data, the selective battery disabling program 150 may implement a convolutional neural network (CNN)-based, you only look once (YOLO) object detector that is trained on historical data from various devices of the same, or a similar, type to the device in which the battery pack is installed. The CNN-based YOLO object detector may provide a percentage of dendrite formation in a specific cell or battery based on the sensor-captured data as compared to the knowledge corpus and historical data available to the selective battery disabling program 150. In at least one embodiment, the selective battery disabling program 150 may utilize a numerical range from zero to 100 percentage points for the percentage of dendrite formation where zero percentage points relates to no dendrite formation and 100 percentage points relates to dendrite formation that causes a short circuit in the cell, battery, or battery pack.

Next, at 206, the selective battery disabling program 150 identifies a cell within the battery pack with a calculated dendrite formation exceeding a threshold value. Using the captured cell status information relating to charge, discharge, operation, and environmental parameters of the cells, the selective battery disabling program 150 may correlate a dendrite formation pattern within the cells and/or the battery pack as a whole. As previously described, the selective battery disabling program 150 may utilize current leakage to determine a rate of dendrite formation within a cell or battery. Additionally, the selective battery disabling program 150 may further utilize the current leakage from two or more cells or batteries within the battery pack for various operational and environmental parameters to identify a pattern of current leakage which, in turn, the selective battery disabling program 150 may utilize to identify a threshold value, or safety threshold, of dendrite formation at which operation of the cell or battery may be unsafe and at risk for a short circuit. Periodically, the selective battery disabling program 150 may analyze predicted levels of dendrite formation to determine whether a cell within the battery pack has a dendrite formation above a threshold limit.

In one embodiment, the selective battery disabling program 150 may utilize historically captured data to generate a knowledge corpus on the dendrite formation pattern on the cells or the battery pack. The selective battery disabling program 150 may also utilize research simulation data of a battery short circuit to identify an amount of acceptable dendrite formation for safe operation of a cell and/or the battery pack. The selective battery disabling program 150 may utilize dendrite formation and short circuit simulation data from a central repository, such as storage 124 or remote database 130, so as to allow for a more robust knowledge corpus that incorporate a wider range of simulation data beyond the cells or battery pack of the current device.

In another embodiment, the selective battery disabling program 150 may initiate a scanning procedure of the cells and/or battery pack as a whole when the calculated dendrite formation value exceeds the safety threshold or a lower threshold value approaching the safety threshold. The selective battery disabling program 150 may scan the cells and/or battery pack using onboard sensors or through an external scanning device, such as an x-ray computed tomography capture device, capable of transmitting the data associated with the cells or battery pack to an onboard iteration of the selective battery disabling program 150. The external scanning device may be installed in a parking area and capable of identifying if additional correction is to be applied to address dendrite formation as well as the operational and/or environmental parameters that may be causing or exacerbating dendrite formation, such as overcharging or charging as high temperatures.

Then, at 208, the selective battery disabling program 150 disables current through the cell. If the selective battery disabling program 150 determines the safety threshold value of dendrite formation has been exceeded, the selective battery disabling program 150 may perform an action that may prevent further dendrite formation and/or a short circuit of the cell, such as, but not limited to, disabling current through the cell. In one embodiment, the selective battery disabling program 150 may disable current through the cell by disconnecting the cells within the battery pack from the other cells, which results in current no longer flowing through the cell during recharge or discharge of the cell.

In another embodiment, when the selective battery disabling program 150 determines the dendrite formation threshold is close to being exceeded (e.g., a lower threshold value that is approaching the safety threshold has been exceeded), the selective battery disabling program 150 may perform a mitigation action on the cell or battery pack. For example, if the selective battery disabling program 150 determines dendrite formation on a cell has exceeded the lower dendrite formation threshold but has not exceeded the safety threshold value itself indicating the dendrite formation has increased but is not yet at an unsafe level, the selective battery disabling program 150 may initiate a remediation action, such as, but not limited to, a cooling system that aims to reduce the impact of heated cells within the battery pack on dendrite formation, that extends the life of the cell. An exemplary remediation action, such as a cooling system as described further in FIG. 3, may create a more appropriate environment for controlling dendrite formation, or otherwise creating an environment less conducive to dendrite formation, and extend a cell's lifespan which may otherwise be reduced by dendrite formation.

In yet another embodiment, the selective battery disabling program 150 may monitor data related to an overall status of the battery pack representative of the battery pack's ability to provide operational power to the device for which it is powering. If the selective battery disabling program 150 determines, due to dendrite formation and/or disabled cells, the battery pack is unable to provide or will soon be unable to provide enough power to operate the device, the selective battery disabling program 150 may transmit a notification to a user through a graphical user interface of the device of which the battery pack is providing power or a communicatively coupled user device, such as EUD 103.

Referring now to FIG. 3, a functional block diagram of a battery pack temperature regulation system 300 according to at least one embodiment. As previously described, when the selective battery disabling program 150 determines the dendrite formation threshold is close to being exceeded (e.g., a lower threshold value that is approaching the safety threshold has been exceeded), the selective battery disabling program 150 may perform a mitigation action on the cell or battery pack. In one embodiment, the mitigation action may be for the selective battery disabling program 150 to engage a liquid cooling system that reduces the heat generated by the battery pack or individual cells 302 either through operation/discharging or charging functions. The battery pack, or individual cells or batteries, may be equipped with a cooling system 304. The cooling system 304 may include an intake duct and an outflow duct connected by various flow ducts that traverse on, in, over, under, or a combination thereof the cells 302 or batteries within the battery pack. A liquid coolant may be pumped or otherwise sent as inflow 306 through the cooling system 304 where it may traverse through the cells 302 of the battery pack and exit the cooling system 302 as outflow 308. Due to the nature of the cells 302 operating at a warmer temperature than the coolant flowing through the cooling system 304 and thermodynamic properties, coolant at the outflow 308 may have a higher measured temperature than coolant at the inflow 306.

It may be appreciated that FIGS. 2-3 provide only an illustration of one implementation and do not imply any limitations with regard to how different embodiments may be implemented. Many modifications to the depicted environments may be made based on design and implementation requirements.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A processor-implemented method, the method comprising:
calculating a dendrite formation value of a cell within a battery pack based on captured sensor data;
in response to determining the dendrite formation value exceeds a safety threshold, disabling the cell.

2. The method of claim 1, further comprising:
in response to determining the dendrite formation value does not exceed the safety threshold but does exceed a preconfigured threshold lower than the safety threshold, performing a remediation action.

3. The method of claim 2, wherein the remediation action comprises activating a cooling system to lower a temperature of the cell to a range less conducive to dendrite formation.

4. The method of claim 1, wherein the calculating utilizes a convolutional neural network (CNN)-based, you only look once (YOLO) object detector, trained using historical data from various devices of a same or similar type as a device in which the cell is installed, to generate a percentage of dendrite formation in the cell.

5. The method of claim 1, wherein the captured sensor data is selected from a group consisting of temperature, a charging detail, an available power state, a usage duration, an amount of recharge, an amount of discharge and any other information related to charge, discharge, operation, or environmental parameters of the cell.

6. The method of claim 1, further comprising:
mapping a location of the cell within the battery pack.

7. The method of claim 1, wherein disabling the cell comprises preventing current from passing through the cell.

8. A computer system, the computer system comprising:
one or more processors, one or more computer-readable memories, one or more computer-readable tangible storage media, and program instructions stored on at least one of the one or more tangible storage media for execution by at least one of the one or more processors via at least one of the one or more memories, wherein the computer system is capable of performing a method comprising:
calculating a dendrite formation value of a cell within a battery pack based on captured sensor data;
in response to determining the dendrite formation value exceeds a safety threshold, disabling the cell.

9. The computer system of claim 8, further comprising:
in response to determining the dendrite formation value does not exceed the safety threshold but does exceed a preconfigured threshold lower than the safety threshold, performing a remediation action.

10. The computer system of claim 9, wherein the remediation action comprises activating a cooling system to lower a temperature of the cell to a range less conducive to dendrite formation.

11. The computer system of claim 8, wherein the calculating utilizes a cognitive neural network (CNN)-based, you only look once (YOLO) object detector, trained using historical data from various devices of a same or similar type as a device in which the cell is installed, to generate a percentage of dendrite formation in the cell.

12. The computer system of claim 8, wherein the captured sensor data is selected from a group consisting of temperature, a charging detail, an available power state, a usage duration, an amount of recharge, an amount of discharge and any other information related to charge, discharge, operation, or environmental parameters of the cell.

13. The computer system of claim 8, further comprising:
mapping a location of the cell within the battery pack.

14. The computer system of claim 8, wherein disabling the cell comprises preventing current from passing through the cell.

15. A computer program product, the computer program product comprising:
one or more computer-readable tangible storage medium and program instructions stored on at least one of the one or more tangible storage media, the program instructions executable by a processor capable of performing a method, the method comprising:
calculating a dendrite formation value of a cell within a battery pack based on captured sensor data;
in response to determining the dendrite formation value exceeds a safety threshold, disabling the cell.

16. The computer program product of claim 15, further comprising:
in response to determining the dendrite formation value does not exceed the safety threshold but does exceed a preconfigured threshold lower than the safety threshold, performing a remediation action.

17. The computer program product of claim 16, wherein the remediation action comprises activating a cooling system to lower a temperature of the cell to a range less conducive to dendrite formation.

18. The computer program product of claim 15, wherein the calculating utilizes a cognitive neural network (CNN)-based, you only look once (YOLO) object detector, trained using historical data from various devices of a same or similar type as a device in which the cell is installed, to generate a percentage of dendrite formation in the cell.

19. The computer program product of claim 15, wherein the captured sensor data is selected from a group consisting of temperature, a charging detail, an available power state, a usage duration, an amount of recharge, an amount of discharge and any other information related to charge, discharge, operation, or environmental parameters of the cell.

20. The computer program product of claim 15, further comprising:
mapping a location of the cell within the battery pack.
